(19) United States
(12) Patent Application Publication
(10) Pub. No.: US 2015/0170926 A1
(43) Pub. Date: Jun. 18, 2015

(54) DIELECTRIC LAYERS HAVING ORDERED ELONGATE PORES

(71) Applicants: David J. Michalak, Portland, OR (US); Robert L. Bristol, Portland, OR (US); Arkaprabha Sengupta, Hillsboro, OR (US); Mauro J. Kobrinsky, Portland, OR (US)

(72) Inventors: David J. Michalak, Portland, OR (US); Robert L. Bristol, Portland, OR (US); Arkaprabha Sengupta, Hillsboro, OR (US); Mauro J. Kobrinsky, Portland, OR (US)

(21) Appl. No.: 14/108,255

(22) Filed: Dec. 16, 2013

(51) Int. Cl. H01L 21/308; H01L 23/50; H01L 21/311

(52) U.S. Cl. CPC H01L 21/3086; H01L 21/3081; H01L 21/31144; H01L 23/50

(57) ABSTRACT

Embodiments of the present disclosure describe dielectric layers and methods for their fabrication and use. In some embodiments, a dielectric layer may include a dielectric material and a plurality of elongate pores. The dielectric material may have a first surface and an opposing second surface spaced away from the first surface in a direction defined by an axis, and may have a Young's modulus (E₀) in the direction defined by the axis. Individual elongate pores of the plurality of elongate pores may extend from the second surface with a longitudinal axis substantially parallel to the axis. The plurality of elongate pores may provide the dielectric layer with a porosity, p, greater than approximately 30%, and the dielectric layer may have a Young's modulus approximately equal to E₀*(1−p) in the direction defined by the axis. Other embodiments may be described and/or claimed.

### FIELD

Embodiments of the present disclosure generally relate to the field of electrical devices, and more particularly, to dielectric layers.

### BACKGROUND

In conventional integrated circuit (IC) technologies, conventional dielectric materials having a dielectric constant of 2.3 and above are currently used to electrically insulate conductive layers. Efforts to develop materials having dielectric constants lower than 2.3 have typically resulted in materials that are too weak to withstand the chemical and mechanical forces exerted during IC device manufacturing. Consequently, the portfolio of conventional dielectric materials currently limits the achievable improvements in electrical and/or mechanical performance of IC devices.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 is a cross-sectional, perspective view of a portion of a dielectric layer, in accordance with some embodiments.

FIG. 2 is a top view of an example arrangement of elongate pores exhibiting various ranges of ordering on a surface of a dielectric layer, in accordance with some embodiments.

FIGS. 3-15 illustrate a dielectric layer subsequent to various fabrication operations, in accordance with some embodiments.

FIG. 16 is a flow diagram of a method of fabricating a dielectric layer, in accordance with some embodiments.

FIG. 17 is a cross-sectional view of a portion of an integrated circuit device including a dielectric layer, in accordance with some embodiments.

FIG. 18 is a block diagram of a computing device that may include a dielectric layer, in accordance with some embodiments.

### DETAILED DESCRIPTION

Embodiments of the present disclosure describe dielectric layers and methods for their fabrication and use. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, vertical/horizontal, above/below and the like. Such descriptions are merely used to facilitate the discussion and are not intended to restrict the application of embodiments described herein to any particular orientation. The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

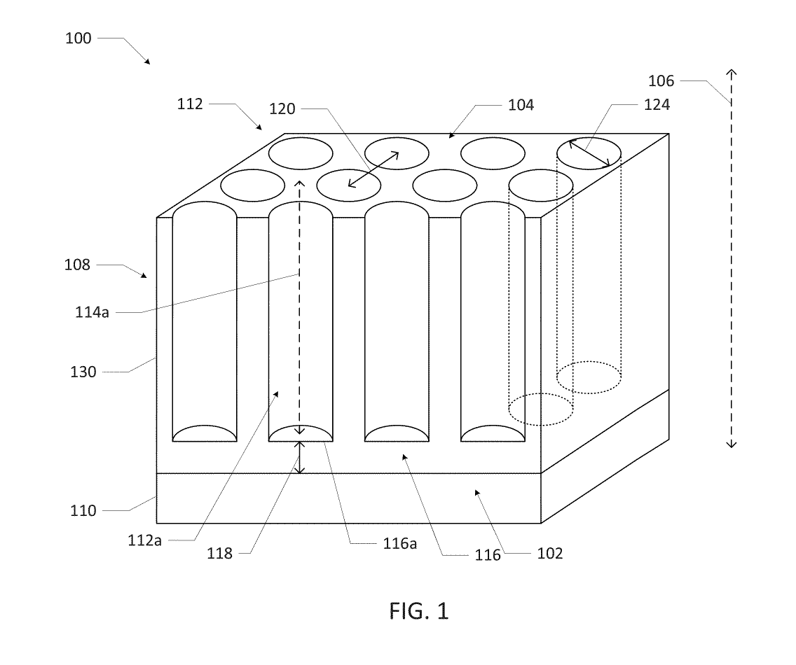

FIG. 1 is a cross-sectional, perspective view of a portion of a dielectric layer 100. In some embodiments, the dielectric layer 100 may be used as or included in an interlayer dielectric (ILD) in an integrated circuit (IC) device. The dielectric layer 100 may include a dielectric material 130 and a plurality of elongate pores 112. The dielectric material 130 may have a first surface 102 and a second surface 104 opposite to the first surface 102. The first surface 102 may be disposed between the second surface 104 and a substrate 110. As used herein, a “substrate” may refer to a base substrate material on which a dielectric layer may be disposed (e.g., a silicon wafer on which an IC die is disposed) and/or any layer or stack of dielectric or other layers upon which a dielectric layer may be disposed (e.g., a metallization layer in an ILD stack). The first surface 102 and the second surface 104 may be spaced away from each other in a direction defined by an axis 106, which may be a vertical axis in the depicted embodiment. An interior 108 of the dielectric material 130 may be disposed between the first surface 102 and the second surface 104.

As noted above, the dielectric layer 100 may include a plurality of elongate pores 112. The elongate pores 112 may provide voids in the dielectric material 130. Individual pores of the elongate pores 112 (e.g., the individual pore 112a) may extend from the second surface 104 into the interior 108 of the dielectric material 130. In some embodiments, each of the elongate pores 112 may have a longitudinal axis that is substantially parallel to the axis 106. For example, the individual pore 112a is depicted in FIG. 1 as having a longitudinal axis 114a that is substantially parallel to the axis 106. The elongate pores 112 may be arranged so that their longitudinal axes are substantially parallel. This ordering may allow the dielectric layer 100 to have a greater mechanical stiffness in one or more directions than dielectric materials having comparable porosities but with voids that are more randomly distributed, as discussed in additional detail below.

In some embodiments, each of the individual pores of the elongate pores 112 may have a common shape. For example, as shown in FIG. 1, each of the elongate pores 112 is a round cylinder. In various embodiments, any one or more of the elongate pores 112 may be a round cylinder, an elliptical cylinder, a rectangular cylinder, a triangular cylinder, a hexagonal cylinder, a helix, and/or any other desired shape. In some embodiments, different ones of the elongate pores 112 may have different shapes. For example, some of the elongate pores 112 may be rectangular cylinders while others of the elongate pores 112 may be elliptical cylinders. These different shapes may be arranged in a regular pattern, as desired. Different shapes for the elongate pores 112 may result in different mechanical properties for the dielectric layer 100. For example, shapes having a linear longitudinal axis (e.g., a circular cylinder) may have higher rigidity than helical or other shapes (which may act more like a spring). The shape of one or more of the elongate pores 112 may be selected to achieve a desired mechanical profile for the dielectric layer 100.

Each of the elongate pores 112 may have a particular set of dimensions. For example, the individual elongate pore 114a in FIG. 1 may be described as a cylinder of diameter 124, ellipsoidal pores may be described by two radii, rectangular cylinders will be characterized by two perpendicular lengths, etc. In some embodiments, different ones of the elongate pores 112 may have substantially similar dimensions. For example, each of the elongate pores 112 in FIG. 1 is depicted having a common diameter approximately equal to the diameter 124. In some embodiments, each of the elongate pores 112 (shaped as round cylinders or another shape) may have a diameter of approximately 14 nanometers, approximately 8 nanometers, or lower. In some embodiments, the individual pores of the elongate pores 112 may have different dimensions. For example, some of the elongate pores 112 may have a diameter of approximately 16 nanometers while others of the elongate pores 112 may have a diameter of approximately 10 nanometers. Differently sized elongate pores may be arranged in a regular pattern. In some embodiments, each of the elongate pores 112 need not have a constant diameter, but may have a varying diameter (varying, e.g., between the first surface 102 and the second surface 104).

In some embodiments, the elongate pores 112 may not extend all the way to the first surface 102. For example, as shown in FIG. 1, the elongate pores 112 may have bottom surfaces 116 (e.g., the bottom surface 116a of the individual pore 112a), and the bottom surfaces 116 may be spaced away from the first surface 102. The distance 118 between the first surface 102 and the bottom surfaces 116 of the elongate pores 112 may be substantially the same between individual pores, or may be different between individual pores. The distance 118 may be adjusted to provide a desired thickness of the material 130 at the first surface 102, which may support the dielectric layer 100 and the elongate pores 112. In some embodiments, the elongate pores 112 may extend all the way from the second surface 104 to the first surface 102.

The porosity of the dielectric layer 100 may be determined by the shape of the elongate pores 112 (e.g., their diameter and depth) and the pitch 120 of the elongate pores 112. As used herein, the “porosity” of a material may be defined as the fraction (or percentage) of the volume of voids in the material over the total volume. For example, a cube of material having outer dimensions of 10 centimeters by 10 centimeters by 10 centimeters may have a porosity of 12.5% if the material included a cubic void measuring 5 centimeters by 5 centimeters by 5 centimeters. In some embodiments, the elongate pores may have a diameter-to-pitch ratio within the range of approximately 0.6 to approximately 1.04. In some embodiments, the elongate pores may have a diameter to pitch ratio within the range of approximately 0.4 to approximately 1.04. The porosity of the dielectric layer 100 may be greater than approximately 50%. In some embodiments, the porosity of the dielectric layer 100 may be greater than approximately 40%. In some embodiments, the porosity of the dielectric layer 100 may be between approximately 40% and 60%, and may have a dielectric constant between approximately 2.0 and 1.6. In some embodiments, the porosity of the dielectric layer 100 may be greater than approximately 60%. In some embodiments, the porosity of the dielectric layer 100 may be between 60% and 80%. In some embodiments, the porosity of the dielectric layer 100 may be between 50% and 90%.

The elongate pores 112 may be arranged in a regular pattern on the second surface 104 of the dielectric material 130. As used herein, a “regular” pattern may be a pattern which nominally or approximately corresponds to a regularly spaced and/or repeating arrangement. The position of individual elongate pores of the elongate pores 112 may deviate from their nominal position in a regularly arrangement, and the elongate pores 112 may still be regularly arranged. Additionally, the dimension of individual elongate pores may deviate from their nominal dimensions. For example, as shown in FIG. 1, the centers of adjacent elongate pores may be spaced apart by a common distance 120. A regular arrangement of the elongate pores 112 on the second surface 104 may take the form of any suitable pattern, such as a square array, a hexagonal array, or other arrangement.

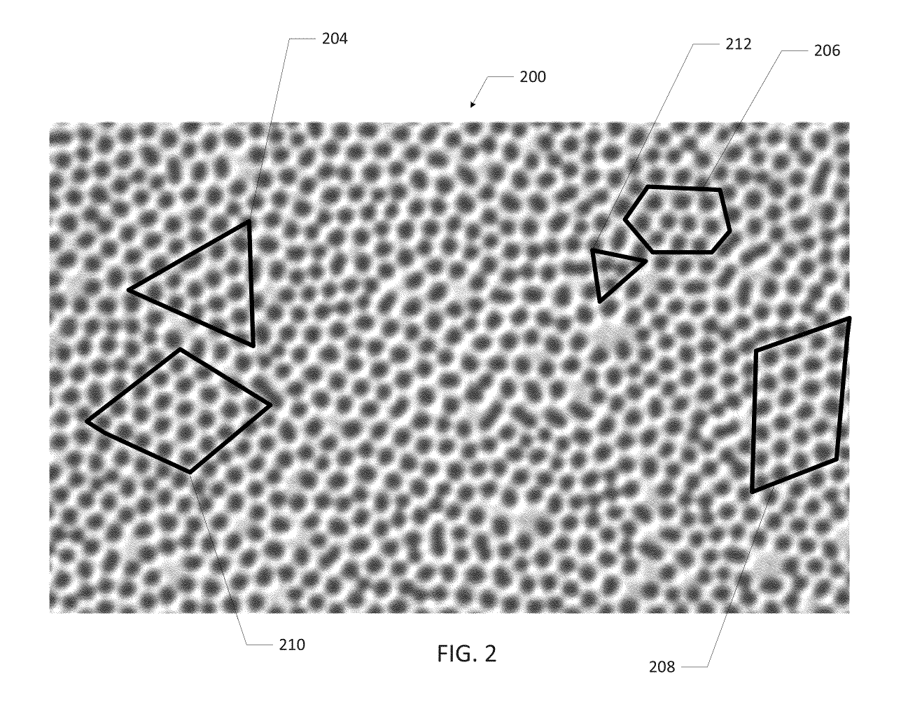

The regularity of the pattern of elongate pores 112 on the second surface 104 may be short-range (e.g., over a distance corresponding to approximately 1-5 pores), medium-range (e.g., over a distance corresponding to approximately 5-50 pores) or long-range (e.g., over a distance corresponding to greater than approximately 50 pores). For example, FIG. 2 is a top view (i.e., a view of the second surface 104) of an example arrangement 200 of elongate pores (e.g., the elongate pores 112) exhibiting various ranges of ordering on the second surface 104. A number of regions 204, 206, 208, 210 and 212 are outlined, each illustrating regions of the arrangement 200 in which the elongate pores (indicated by the darker shapes) are arranged in a regular pattern. The regions 204, 206, 208, 210 and 212 highlight various regions of short- and medium-range ordering within the arrangement 200. As illustrated in FIG. 2, in some embodiments, the arrangement of the elongate pores 112 may be regular within one or more separate regions, but the arrangements may be different between the two regions, or oriented differently within the two regions (e.g., rotated by a certain amount). The arrangement of the elongate pores 112 on the second surface 104 may be constrained by the fabrication techniques used to form the dielectric layer 100 (e.g., as discussed below with reference to the directed self-assembly fabrication technique illustrated in FIGS. 5-8).

The ability of the dielectric layer 100 to withstand compressive and tensile forces may be related to the porosity of the dielectric layer 100 and the arrangement of the elongate pores 112, among other things. In some embodiments, the relationship between the porosity of the dielectric layer 100 and the Young's modulus of the dielectric material 130 (prior to the formation of the elongate pores 112) may be linear. As used herein, the “Young's modulus” may be an “effective” Young's modulus, which may refer to the macroscopic value measured for the dielectric layer 100 (including the dielectric material 130 and the elongate pores 112). In particular, when the dielectric material 130 (prior to formation of the elongate pores 112) has a Young's modulus in the direction defined by the axis 106 equal to E₀, and when the porosity of the dielectric layer 100 (due to the elongate pores 112) is p, the Young's modulus of the dielectric layer 100, E, may be approximately equal to E₀*(1−p) in the direction defined by the axis 106. Table 1 provides example values of the Young's modulus E in the direction defined by the axis 106 for a dielectric layer 100 having various porosities. Various embodiments of the dielectric layer 100 may have Young's moduli that fall within +/−20% of the relationship of Table 1 while remaining effectively linear.

TABLE 1
Example porosities p for the dielectric layer 100 and corresponding
Young's moduli in the direction defined by the axis 106 for a dielectric
material 130 having a nominal Young's modulus of E₀.

| | Young's modulus | Young's modulus |
|---|---|---|
| | of the dielectric | of the dielectric |
| | layer 100 relative to the Young's | layer 100 for a dielectric |
| porosity | modulus of the dielectric | material 130 having E₀ = 32 |
| (p, %) | material 130 (E/E₀) | gigapascals (gigapascals) |
| 0 | 1 | 32.2 |
| 13.4 | 0.866 | 27.9 |
| 26.1 | 0.739 | 23.8 |
| 35.7 | 0.643 | 20.7 |
| 44.9 | 0.551 | 17.7 |
| 52.8 | 0.472 | 15.2 |
| 58.5 | 0.415 | 13.4 |

In some embodiments, the porosity of the dielectric layer 100 may be between 60% and 80%, and the dielectric layer 100 may have a Young's modulus greater than or equal to approximately 5 gigapascals in the direction defined by the axis 106. Some embodiments of the dielectric layers disclosed herein may exhibit Young's moduli of approximately 20, 17, 15 and 13 gigapascals in the longitudinal direction (the direction defined by the axis 106) and 11, 8, 5 and 4 gigapascals in the transverse direction (the direction perpendicular to the axis 106) at porosities of approximately 35%, 45%, 52% and 58%, respectively. As dielectric materials having various Young's moduli are identified and developed, the techniques disclosed herein may be applied to fabricate dielectric layers having Young's moduli that scale with the porosity. As discussed below, existing porous dielectric films may have randomly distributed ellipsoidal pores, for which the Young's modulus rapidly decreases (much faster than linearly) with increasing porosity, resulting in a dielectric material whose material properties are inadequate for the material to be readily integrated into an IC device. A number of additional/alternative properties and advantages of various embodiments of the dielectric layers disclosed herein are discussed below.

The dielectric constant of the dielectric layer 100 may be related to the dielectric constant of the dielectric material 130. In particular, when the dielectric material 130 (prior to formation of the elongate pores 112) has a dielectric constant equal to κ0, and when the porosity of the dielectric layer 100 (due to the elongate pores 112) is p, the dielectric constant of the dielectric layer 100, κ, may be approximately equal to κ0(1−p). Various embodiments may exhibit variation of 10-20% around this relationship while remaining effectively linear. As dielectric materials having various dielectric constants are identified and developed, the techniques disclosed herein may be applied to fabricate dielectric layers having dielectric constants that scale with the porosity.

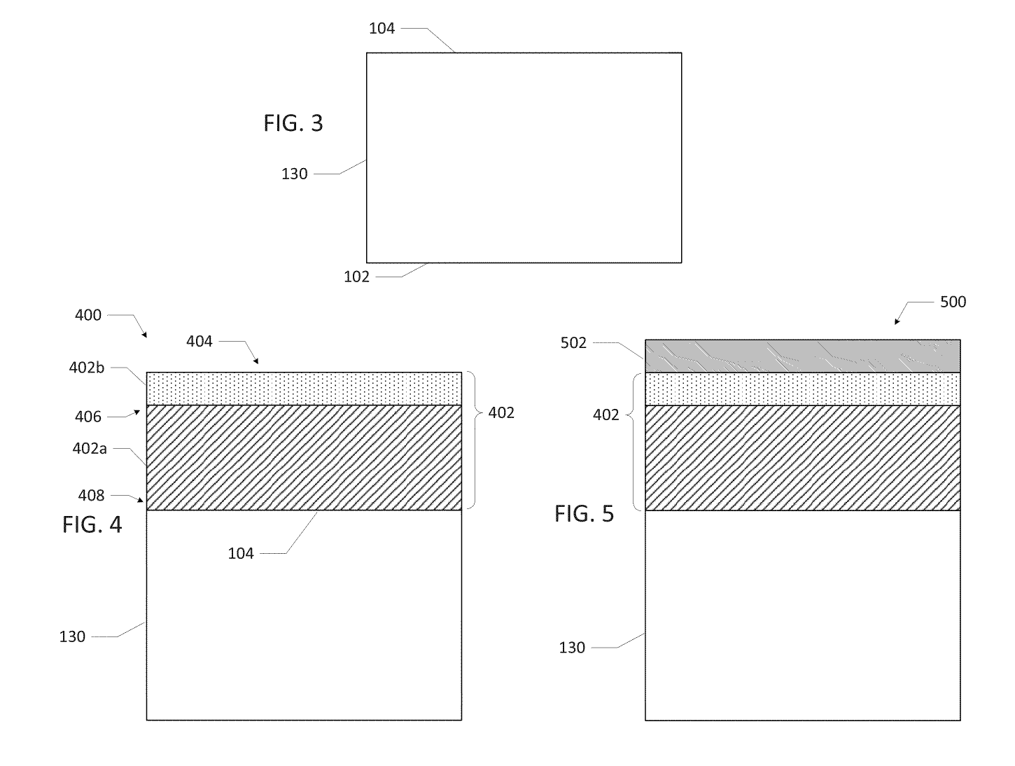

FIGS. 3-15 illustrate various stages in an illustrative process for fabrication of a dielectric layer, in accordance with some embodiments. The illustrated process may have an advantageously lower cost than other fabrication methods (e.g., lithographic methods). For illustrative purposes, the assemblies depicted as part of various fabrication stages illustrated in FIGS. 3-15 are described with reference to the fabrication of the dielectric layer 100 of FIG. 1, but such stages may be applied as suitable to fabricate any of the dielectric layer embodiments described herein. The particular processes illustrated herein for fabrication of a dielectric layer are not exclusive, and any suitable process may be used to fabricate the dielectric layers disclosed herein. For example, in some embodiments, a mask for the pore structure of the dielectric layer 100 may be fabricated using photon, electron beam, or extreme ultraviolet lithographic techniques. These lithographic techniques, however, may be more cost- and resource-intensive than the fabrication processes discussed below with reference to FIGS. 3-15.

Referring to FIG. 3, the dielectric material 130 is shown. The dielectric material 130 may include the first surface 102 and the second surface 104. The dielectric material 130 may be disposed on a substrate (e.g., so that the first surface 102 is between the substrate and the second surface 104), but no substrate is depicted in FIGS. 3-15 for ease of illustration. In some embodiments, the dielectric material 130 may be a conventional non-porous or low-porosity material used as an ILD in existing IC devices, such as silicon dioxide, carbon-doped silicon oxide, fluorine-doped silicon oxide, fluorocarbon (CFx, which may be more like a fluorinated amorphous carbon film than a graphite material), silicon carbide, silicon oxycarbide, silicon nitride, silicon oxynitride, oxygen-doped silicon carbide, carbosilanes and/or carbosiloxanes, for example. The dielectric material 130 may be deposited on the substrate (e.g., a patterned or non-patterned wafer) and, in some cases, cured (e.g., through a thermal process or a thermal process including exposure to electron beams and/or ultraviolet or infrared photons).

Referring to FIG. 4, an assembly 400 is depicted subsequent to deposition of a hardmask 402 on the second surface 104 of the dielectric material 130. A surface 404 of the hardmask 402 may be exposed. In some embodiments, the hardmask 402 may include two or more hardmasks; as shown in FIG. 4, the hardmask 402 may include a first hardmask 402a and a second hardmask 402b. In some embodiments, the first hardmask 402a may be formed from titanium, titanium nitride, silicon nitride, amorphous carbon, a cross-linked hydrocarbon polymer, or another material that has a composition that will not be substantially etched during etching of the dielectric material 130. In some embodiments, the second hardmask 402b may be formed from silicon dioxide, silicon oxide, silicon antireflective coating (SiARC), silicon carbide, titanium, titanium nitride, silicon nitride, titanium oxide, titanium dioxide, aluminum oxide, or another material having a composition that can be selectively etched without significant damage to the first hardmask 402a and the directed self-assembly (DSA) material 502 (discussed below). In some embodiments, the second hardmask 402b may have a similar composition (and etch rate) to the dielectric material 130. The first hardmask 402a may be disposed between the second surface 104 of the dielectric material 130 and the second hardmask 402b, and may have a surface 408 adjacent to the dielectric material 130 and an opposing surface 406 disposed adjacent to the second hardmask 402b. Although two hardmasks are illustrated in FIG. 4, additional or fewer hardmasks may be used and the techniques disclosed herein extended or modified naturally to include the additional or fewer hardmasks.

Referring to FIG. 5, an assembly 500 is depicted subsequent to deposition of a directed self-assembly (DSA) material 502 on the surface 404 of the hardmask 402 of the assembly 400. The DSA material 502 may be deposited such that the hardmask 402 is disposed between the DSA material 502 and the dielectric material 130. The DSA material 502 may include two components, an upper block copolymer and a lower “neutral” layer. The lower layer may provide a surface with equal attraction between both blocks of the upper block copolymer. The lower layer may be composed of alternating short lengths of the two blocks of the upper block copolymer in a ratio approximately the same as that of the upper block copolymer. The second component may be a diblock copolymer having a Flory-Huggins interaction parameter that is large enough for the two blocks to segregate into two domains of a particular size and shape when exposed to a thermal or solvent-based anneal. The size and shape of the domains may depend on the interaction parameter and the relative molecular weights of the blocks, for example. The diblock copolymer may be, for example, polystyrene-block-polymethyl methacrylate) (PS-PMMA). The ratios of the two polymers included in the first material may be selected to match the ratio of the blocks in the second material. The chemical properties of the two blocks of the diblock copolymer may be selected to be sufficiently different that one block may be selectively etched after thermal anneal to leave behind the remaining block, as discussed below. Deposition of the DSA material 502 may comport with well-known techniques, such as spin-casting, and configurations, in some embodiments.

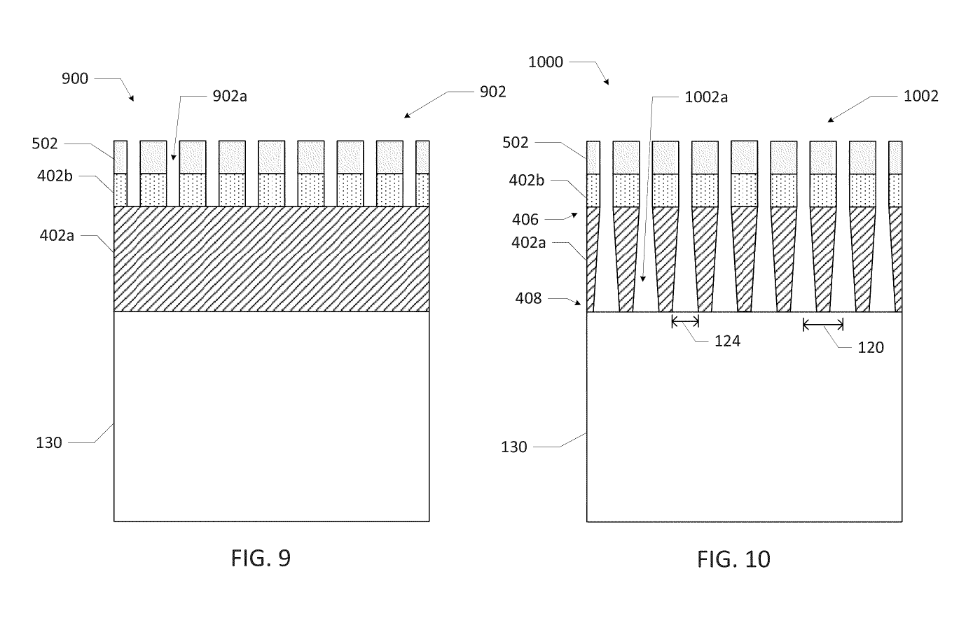

In some embodiments, the materials for the first hardmask 402a, the second hardmask 402b, and the DSA material 502 may be selected so that the remaining block of DSA material 502 remains substantially intact during etch of the second hardmask 402b (as discussed below with reference to FIG. 9). For example, many commercially available DSA materials are highly carbon-based polymers, so when such a material is used for the DSA material 502, the material for the second hardmask 402b may be selected to avoid high carbon materials (e.g., CHMs, amorphous diamond, diamond-like carbon, or other materials) whose compositions are similar enough to the DSA material 502 that etching the second hardmask 402b may also etch the DSA material 502.

In some embodiments, the surface 404 of the second hardmask 402b may be prepared prior to deposition of the DSA material 502. This preparation may include applying a brief, low-power oxygen plasma to oxidize the surface 404 of the second hardmask 402b prior to deposition of the DSA material 502. This “low-power” plasma may have sufficient radio frequency (RF) power to sustain the plasma, but may have a small direct current (DC) bias applied to a supporting electrostatic chuck in order to minimize the kinetic energy of the ions and thereby avoid sputtering effects. Other techniques for oxidizing the second hardmask 402b may include treatment with ozone, treatment with oxidizing wet chemistries, and/or plasma treatments with hydrogen, helium, argon, nitrogen, ammonia, carbon dioxide, and/or carbon monoxide, for example. In some embodiments, the lower layer of the DSA material 502 may be applied to the oxidized surface 404.

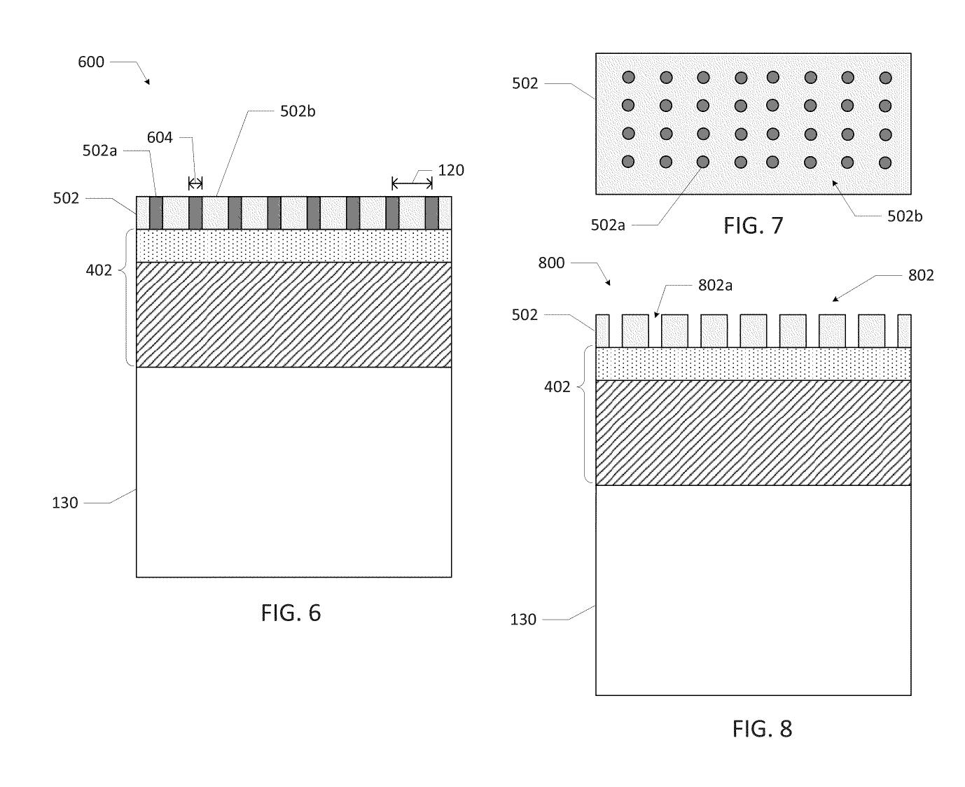

Referring to FIG. 6, an assembly 600 is depicted subsequent to a thermal anneal of the assembly 500. The thermal anneal may take place in the approximate temperature range of 100 degrees Celsius to 450 degrees Celsius, and may enable the self-assembly of the DSA material 502 into aggregate structures. FIG. 7 is a top view of the DSA material 502 after the thermal anneal. In FIGS. 6 and 7, the DSA material 502 is shown as having a regular square lattice of cylindrical aggregate structures, but the lattice may be triangular, Kagome, honeycomb, rhombic, rectangular, parallelogramic, Bethe or others, and the order may be periodic, quasi-periodic, short-range ordered, or randomly ordered geometry (which may still have a strong mechanical strength in the longitudinal direction, as discussed below). In FIGS. 6 and 7, one block of the diblock copolymer is indicated as 502a, while the second block of the diblock copolymer is indicated as 502b. As shown, in some embodiments, the block 502a may aggregate into a vertically oriented array of cylinders separated by a matrix of the block 502b. The cylinders of the block 502a may have a common diameter 604, and centers of nearest neighbor cylinders may be spaced apart by a distance 120 (i.e., may have a pitch equal to the distance 120). A variety of DSA materials may be used to achieve various aggregate structures of various sizes, including some forming aggregate structures (e.g., the structures formed by the block 502a) having a diameter 604 of approximately 14 nanometers and a pitch distance 120 of approximately 34 nanometers, for example. Some DSA materials may form aggregate structures having a diameter 604 of approximately 8 nanometers and a pitch distance 120 of approximately 16 nanometers. In some embodiments, the DSA material 502 may have a diameter-to-pitch ratio in the range of approximately 0.32 to approximately 0.48. Smaller pitches and diameters are contemplated (e.g., using inorganic or nanoparticle-based DSA materials, or shrink techniques).

Referring to FIG. 8, an assembly 800 is depicted subsequent to selective etch of the DSA material 502 of the assembly 600 to form a plurality of template pores 802 in the DSA material 502. Etch of one of the DSA aggregate structures selective to the other aggregate structure can be accomplished via a dry etch technique (e.g., using oxygen and argon with a low bias power) or a wet etch technique (e.g., the application of ultraviolet light of wavelengths of approximately 193 nanometers and below, followed by the application of acetic acid), for example. Each of the template pores 802 (e.g., the template pore 802a) may correspond to a particular aggregation of the block 502a in the DSA material 500, and may have substantially the same diameter (e.g., the diameter 604) as the corresponding aggregation.

Referring to FIG. 9, an assembly 900 is depicted subsequent to etching the second hardmask 402b of the assembly 800 to form a plurality of template pores 902. In some embodiments, each of the individual pores of the template pores 902 (e.g., the individual template pore 902a) may have an area approximately equal to the area of a corresponding individual pore of the template pores 802. In some embodiments, the second hardmask 402b may be etched using a dry etch technique (e.g., a fluorine-based etch chemistry such as fluoromethane (CH3F), or difluoromethan (CH2F2), or fluoroform (CHF3), or hexafluoroethane (C2F6), or sulfur hexafluoride (SF6) or carbon tetrafluoride (CF4), or a halogen-based etch chemistry such as chlorine or bromine) or a wet etch technique (e.g., a hydrofluoric acid chemistry when the second hardmask 402b is formed from aluminum oxide), for example.

Referring to FIG. 10, an assembly 1000 is depicted subsequent to etching the first hardmask 402a of the assembly 900 to form a plurality of template pores 1002. In some embodiments, each of the individual pores of the template pores 1002 (e.g., the pore 1002a) may have an area greater than an area of a corresponding individual pore of the template pores 802 (and/or the corresponding individual pore of the template pores 902). In particular, the radius of the etched area may be increased from the surface 406 of the first hardmask 402a to the surface 408 of the first hardmask 402a to form the template pores 1002 at the surface 406 (having a desired diameter 124). The diameter of the etched area may be controllably increased during the etching process of the first hardmask 402a by isotropically etching the material of the first hardmask 402a with a selective etch or ash that will not consume either the dielectric material 130 or the second hardmask 402b. The pore 1002a may not taper gradually with distance as shown in FIG. 10, but may “bellow” in the middle or have another shape, depending upon the particular etch. The distance 120 between the center of the template pores 1002 (the “pitch”) may be substantially the same as the distance between the centers of the template pores 802 in the DSA material 502. Etching may be terminated once the template pores 1002 reach a target diameter at the surface 408. If an isotropic etch is used, the pore diameter of the first hardmask 402a at the upper surface 406 may be controllably larger than the pore size 604 (embodiment not shown).

In some embodiments, one or more of the hardmasks 402 may not be included, and the pattern formed in the thermally annealed DSA material 502 (e.g., as shown in FIG. 6) may be directly transferred from the DSA material 502 into the dielectric material 130. Such embodiments may be advantageous when there is good etch selectivity between the remaining DSA material 502 and the dielectric material 130, and/or when the dielectric material 130 is sufficiently thin so that the DSA material 502 may serve as an effective mask. Embodiments in which both a DSA material and a hardmask are used may advantageously separate patterning (e.g., via the DSA material) from dielectric etch resistance (provided by the hardmask).

Referring to FIG. 11, an assembly 1100 is depicted subsequent to etching the dielectric material 130 of the assembly 1000 to form the plurality of elongate pores 112. Each of the elongate pores 112 (e.g., the individual elongate pore 112a) may extend from the second surface 104 of the dielectric material 130 toward the first surface 102. The depth of the elongate pores 112 (and consequently, the distance 118 between the first surface 102 and the bottom surfaces 116) may be controlled by terminating the etch at a desired depth. The dielectric material 130 may be etched using any suitable process (including those commonly referred to as “ILD etch processes”). For example, tetrafluoromethane,fluoroform, difluoromethane, fluoromethane, hexafluoroethane, 1,3-hexafluorobutadiene, octafluorocyclobutane, carbon monoxide, carbon dioxide, nitrogen, argon, and/or oxygen (in any combination) may be used for etching. In some embodiments, the first hardmask 402a may be formed from a material resistant to chemical reaction with the material used to etch the dielectric material 130 (e.g., those listed above), such as a cross-linked hydrocarbon polymer. As shown in FIG. 11, in some embodiments, the material of the second hardmask 402b may be consumed during the etch of the dielectric material 130.

As noted above, in some embodiments, one or more of the hardmasks 402 may not be included, and the pattern formed in the thermally annealed DSA material 502 (e.g., as shown in FIG. 6) may be directly transferred from the DSA material 502 into the dielectric material 130. However, when the DSA material 502 is formed from relatively mechanically weak polymers (such that the DSA material 502 may be degraded during etch of the dielectric material 130, e.g., by sputtering), or when the DSA material 502 does not have a desired porosity and geometry for patterning the dielectric material 130 directly, one or more hardmasks may be advantageously used. In some such embodiments, the one or more hardmasks (e.g., the hardmasks 402a and 402b) interposed between the DSA material 502 and the dielectric material 130 may allow the diameters of the template pores in the DSA material 502 to be controllably increased before patterning the dielectric material 130. In some such embodiments, the one or more hardmasks 402 may be mechanically stronger than the DSA material 502, and thus may compensate for the mechanical weakness of the DSA material 502 in the patterning of the dielectric material 130. For example, in some embodiments, the first hardmask 402a and the DSA material 502 may be selected to be similar in material composition (e.g., both including high carbon content, with the first hardmask 402a formed from, e.g., a hydrocarbon polymer material), while the second hardmask 402b and the dielectric material 130 may be selected to be similar in material composition (e.g., both including high silicon content, with the second hardmask 402b formed from, e.g., a silicon-containing anti-reflective coating (SiARC) material). When the template pores 1002 are etched from the first hardmask 402a, the etch chemistry (e.g., a nitrogen/hydrogen ash or an oxygen/argon ash) may remove the remaining DSA material 502 because of their similar compositions. In some embodiments, the DSA material 502 may have a thickness that is less than a thickness of the first hardmask 402a, such that all of the DSA material 502 may be removed when etching of the first hardmask 402a is complete. When the dielectric material 130 is etched (e.g., as shown in FIG. 11), the etch chemistry may remove the remaining second hardmask 402b because of their similar compositions. In some embodiments, the second hardmask 402b may have a thickness that is less than a desired depth of etch in the dielectric material 130, such that all of the second hardmask 402b may be removed when etching of the dielectric material 130 is complete.

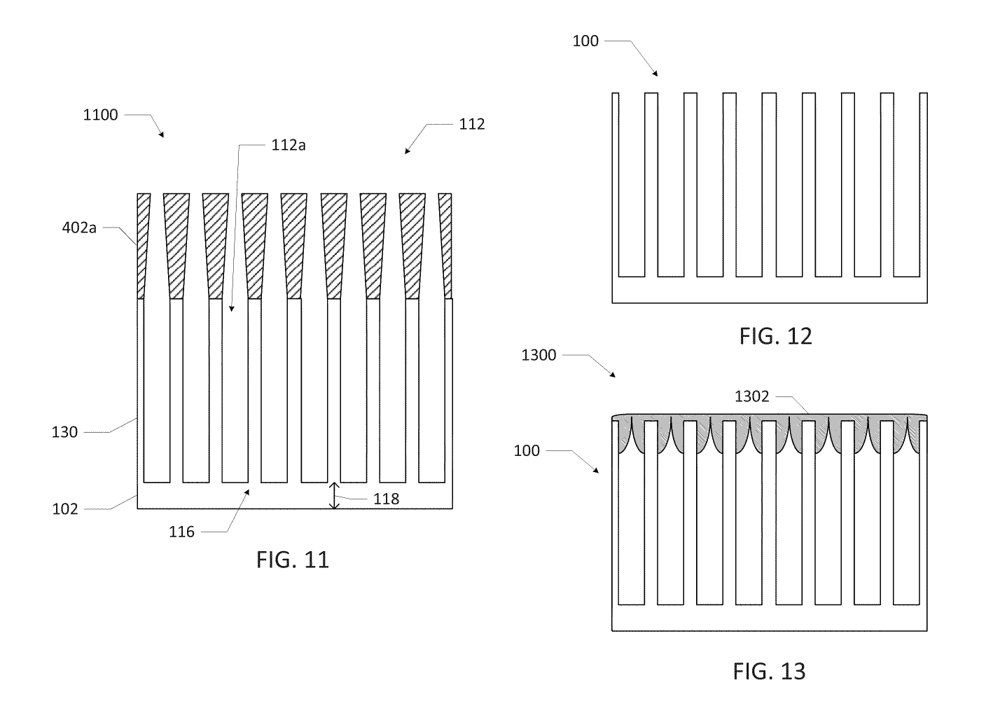

Referring to FIG. 12, the dielectric layer 100 is depicted subsequent to removal of the first hardmask 402a of the assembly 1100 via a selective etch or ash. Examples of suitable techniques include an oxygen ash, a hydrogen/nitrogen ash, an oxygen/argon ash, a helium/hydrogen ash, or a hydrogen-based downstream ash. These etches or ashes may not alter the elongate pores 112 or the dielectric layer 130, thereby preserving the dielectric layer 100. In some embodiments, the porosity of the dielectric layer 100 may be in the range of approximately 20% to approximately 90%, depending on the amount of radial increase in the pores of the first hardmask 402a during etching. In some embodiments, the surfaces of the elongate pores 112 may require wet chemical cleaning to remove residual etch polymer, and/or the dielectric material 130 may be cured (thermal, UV, IR) after cleaning.

Referring to FIG. 13, the assembly 1300 is depicted subsequent to adding a cap 1302 to the dielectric layer 100. The cap 1302 may be formed from the same material as the dielectric material 130, or any other suitable dielectric material, such as any of the materials described herein with reference to the dielectric material 130. In some embodiments, the cap 1302 may provide a surface upon which patterning, metallization, or other processing operations may be performed. In some embodiments, the cap 1302 may be formed by using a “breadloafing” deposition technique in which a plasma is arced to deposit dielectric material on the dielectric layer 100. The precursor molecules used for deposition may accumulate at the upper openings of the elongate pores 112 so that the openings “pinch off” to form a cap after a sufficient amount of the material has been deposited. The cap 1302 may be substantially non-porous. The cap 1302 may also be medium to low porosity (e.g., having a porosity less than approximately 30%). Other suitable capping techniques may also be used. In some embodiments, no cap may be formed on the dielectric layer 100 prior to additional processing operations, or a cap may be formed after some processing operations but before others.

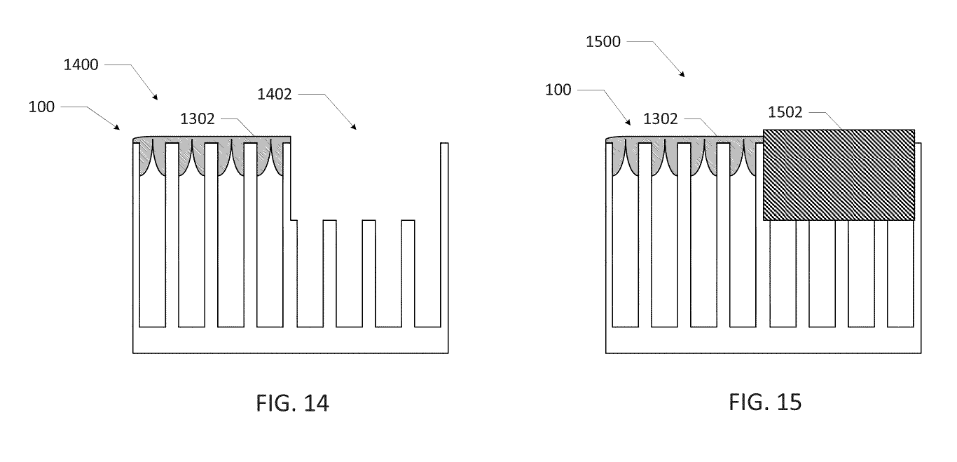

Referring to FIG. 14, the dielectric layer 100 is depicted subsequent to a patterning operation. In particular, a trench 1402 is shown as formed in the second surface 104 of the dielectric layer 100. In some embodiments, the dielectric layer 100 may be patterned with any standard trench and via patterning techniques known in the art. For example, one or more additional hardmasks can be used, followed by spin-expose and development of a resist. Hardmask etch, trench patterning and hardmask removal and clean procedures may follow. Similar steps can be followed to pattern vias in the dielectric layer 100, if desired.

In some embodiments, the plurality of elongate pores 112 may be temporarily filled with a fill material (such as a polymer such as PMMA, polystyrene or polybutadiene, or a refractory material, not shown) during patterning and metal fill to support controlled etching and/or fill by making the dielectric layer 100 mechanically stronger and/or more chemically inert (by blocking infiltration of chemicals into the pores 112). This process may be referred to as “pore-stuffing.” The fill material may be removed after patterning, metal deposition, or metal polish, in various embodiments. For example, highly porous films may undergo mechanical stress during barrier deposition processes (e.g., deposition of tantalum nitride/tantalum, a dual layer material that blocks copper diffusion), and thus in some embodiments, the fill may be removed after chemical-mechanical polishing (e.g., when the dielectric layer 100 is exposed between patterned metal lines if the cap 1302 is removed during polish, or if the cap 1302 is semi-porous, the fill material may be removed through pores of the cap 1302). Polymer fill materials may be removed by an ashing process using a hydrogen-based plasma, or thermally decomposed, for example. More refractory materials, such as silicon dioxide, titanium dioxide and titanium nitride, may be removed using a chemical wet etch selected to avoid oxidizing or damaging any metal lines or other components.

Referring to FIG. 15, the dielectric layer 100 is depicted subsequent to a metallization operation. In particular, a metal 1502 may be disposed in the trench 1402. Prior to metallization, the elongate pores 112 may be sealed with a variety of treatments or by depositing a thin layer of material, typically in the range of 1-2 nanometers, by spin-on or chemical vapor deposition techniques. For example, a barrier (formed from tantalum, tantalum nitride, titanium nitride, aluminum, or a combination of such materials) may be deposited, followed by deposition of a metal seed layer (e.g., a copper seed layer), followed by metal deposition (e.g., deposition of copper, typically by electrochemical plating). The surface of the metallized dielectric layer 100 may then be planarized using chemical-mechanical polishing (CMP) or another suitable planarization technique.

Various ones of the fabrication operations and stages represented in FIGS. 3-15 may be omitted or repeated as desired in the manufacture of an IC or other device. For example, a first dielectric layer may be built on a silicon or other substrate in accordance with the fabrication techniques of FIGS. 3-15, and one or more additional dielectric layers may be formed on top of this dielectric layer and/or metal or other layers formed there between by repeating one or more of the operations illustrated in FIGS. 3-15. The substrate may contain lower interconnects and/or active logic devices.

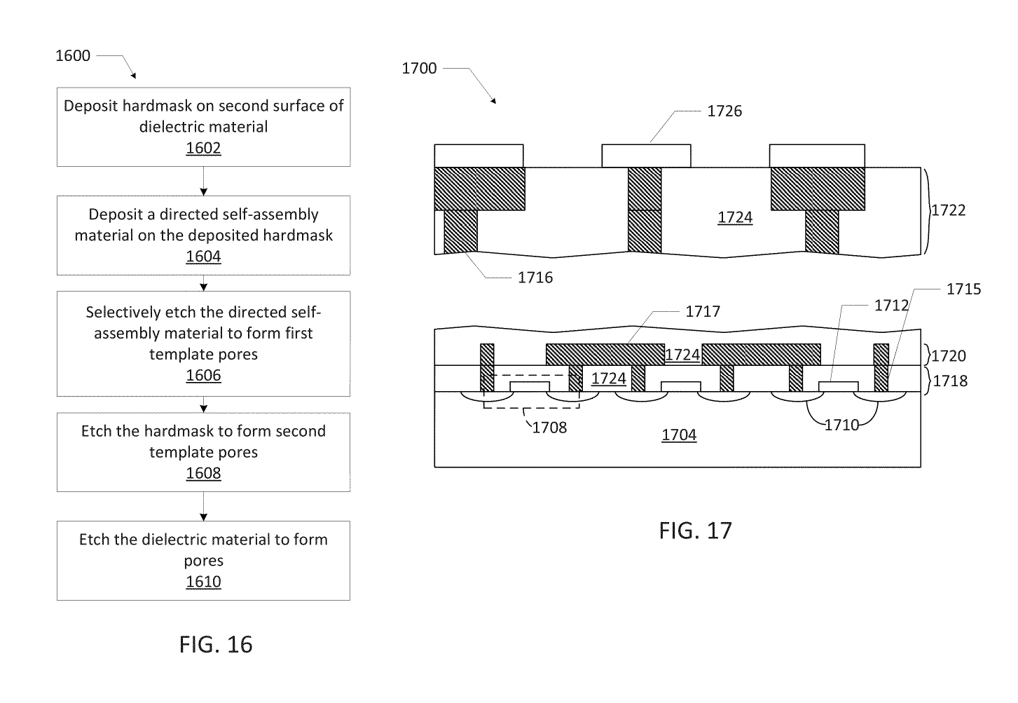

FIG. 16 is a flow diagram of a method 1600 of fabricating a dielectric layer, in accordance with some embodiments. The operations of the method 1600 may be illustrated with reference to the dielectric layer 100 and the fabrication operations discussed above with reference to FIGS. 1-14 for illustrative purposes, but the method 1600 may be used to form any appropriate dielectric layer. Various operations are described herein as multiple discrete operations for ease of illustration. However, the order of description should not be construed as to imply that these operations are necessarily order dependent, or need be separated into discrete operations.

At the operation 1602, a hardmask may be deposited on a second surface of a dielectric material. The second surface may be opposite to a first surface of the dielectric material that is disposed between the second surface and a substrate. For example, the hardmask 402 (FIG. 4) may be deposited on the second surface 104 of the dielectric material 130, which may be opposite to the first surface 102. The first surface 102 may be disposed between the second surface 104 and the substrate 110. In some embodiments, a surface of the hardmask 402 that faces away from the dielectric material 130 may be oxidized (e.g., by a low-power oxygen etch or other process) prior to the operation 1604. In some embodiments, the hardmask of the operation 1602 may include two or more hardmasks (e.g., as discussed above with reference to FIGS. 3-15). For example, in some embodiments, the hardmask of the operation 1602 may include first and second hardmasks, with the first hardmask disposed between the second hardmask and the second surface of the dielectric material.

At the operation 1604, a DSA material may be deposited on the deposited hardmask. For example, the DSA material 502 (FIG. 5) may be deposited on the hardmask 402.

At the operation 1606, the DSA material may be selectively etched to form a first plurality of template pores in the DSA material. For example, a first plurality of template pores 802 (FIG. 8) may be formed in the DSA material 502.

At the operation 1608, the hardmask may be etched to form a second plurality of template pores in the hardmask. An individual pore of the second plurality of template pores may have an area greater than an area of a corresponding individual pore of the first plurality of template pores. For example, the hardmask 402 may be etched to form the template pores 1002 (FIG. 10), each of which may have an area greater than an area of corresponding template pores 802. In some embodiments, the hardmask etched at the operation 1608 may include first and second hardmasks, with the first hardmask disposed between the second hardmask and the second surface of the dielectric material. In some such embodiments, the operation 1608 may include etching the second hardmask to form a third plurality of template pores in the second hardmask. An individual pore of the third plurality of template pores may have an area approximately equal to the area of a corresponding individual pore of the first plurality of template pores. For example, the second hardmask 402b may be etched to form the template pores 902 (FIG. 9), each of which may have an area approximately equal to the area of corresponding template pores 802.

At the operation 1610, the dielectric material may be etched to form a plurality of pores. Individual pores of the plurality of pores may extend from the first surface towards the second surface. For example, the dielectric material 130 may be etched to form the elongate pores 112 (e.g., as shown in FIG. 11).

The method 1600 may include one or more additional operations in various embodiments. In some embodiments, the method 1600 may further include removal of any DSA material and/or hardmask remaining after the dielectric material is etched to form the elongate pores. For example, the first hardmask 402a may be selectively etched from the dielectric layer 100 after the formation of the elongate pores 112 (FIG. 12). The method 1600 may also include patterning and/or metallization, as discussed above with reference to FIGS. 14-15.

Various embodiments of the dielectric layers disclosed herein may provide one or more advantages over conventional dielectric materials. In particular, embodiments of the dielectric layers disclosed herein may achieve dielectric constants less than 2.0. In particular, some of the dielectric layers disclosed herein may have a dielectric constant between approximately 1.2 and approximately 1.5. This performance represents a substantial improvement over baseline polysilicate or carbosilane materials (having a dielectric constant of approximately 3.5 when non-porous) that are made porous upon the inclusion of random void-forming materials discussed below (which typically have a dielectric constant greater than 2.0).The low dielectric constants of various ones of the embodiments disclosed herein may reduce the capacitance of the dielectric layer within an IC device beyond what is expected for randomly mixed porous materials, reducing the signal delay caused by resistive-capacitive effects and thereby improving electrical performance.

Additionally, various embodiments may achieve a mechanical stiffness (represented, e.g., by the Young's modulus of the dielectric layer in one or more directions) that is greater than the mechanical stiffness of existing dielectric thin films having comparable or greater dielectric constants. These existing films are typically formed by randomly mixing a backbone precursor material (e.g., an organosilane or carbosilane) with a porogen material (e.g., a hydrocarbon). These materials may be formed into a matrix, and the porogen material may be selectively burned or etched out of the matrix to form a porous material with substantially randomly distributed voids. The porosity of the resulting material is a function of the loading volume of the porogen material (i.e., the volume of the matrix occupied by porogen material), and thus porosity may be increased by increasing the relative amount of porogen. However, at high loading volumes, the matrix will no longer include a continuous interconnected network of backbone material, and thus, upon burn out of the porogen, the material will collapse or become mechanically very weak. Experimentally, the maximum achievable porosity using this approach may be approximately 50%-60% for conventional types of molecular precursors exhibiting 3-6 bonding directions with neighboring molecules. At porosities close to this maximum porosity, materials produced using such conventional approaches have mechanical strengths that are too low to withstand the tensile and compressive forces typically encountered in IC fabrication operations (e.g., during back end of line processing and assembly) and thus may mechanically fail, causing cracks and fractures that may impede or destroy the operational functionality.

By contrast, in various ones of the embodiments disclosed herein, the introduction of ordering to the voids of a dielectric material (e.g., by alignment of elongate pores in a direction substantially parallel to a common axis) may allow porosities greater than the 50%-60% achievable using existing approaches, with improved mechanical performance along a direction that is beneficial for device fabrication. In particular, the dielectric layers having commonly oriented elongate pores (e.g., cylindrical pores) may have a substantially improved mechanical stiffness in the direction of the longitudinal axis of the pores, and may also exhibit improved performance in the transverse direction relative to dielectrics exhibiting disordered porosity in three dimensions. In particular, when the dielectric material 130 (prior to formation of the elongate pores 112) has a Young's modulus in the direction defined by the axis 106 equal to E₀, and when the porosity of the dielectric layer 100 (due to the elongate pores 112) is p, the Young's modulus of the dielectric layer 100, E, may be approximately equal to E₀*(1−p) in the direction defined by the axis 106 (the longitudinal direction). For example, as noted above, various embodiments of the dielectric layers disclosed herein may exhibit Young's moduli of approximately 21, 18, 15 and 13 gigapascals in the longitudinal direction and 11, 8, 5 and 4 gigapascals in the transverse direction at porosities of approximately 36%, 45%, 53% and 59%, respectively. Existing dielectric materials with randomly distributed voids (e.g., those generated using conventional plasma-enhanced chemical vapor deposition) may be substantially isotropic, and may exhibit Young's moduli of approximately 11, 9, 7, and 5 gigapascals at porosities of approximately 5%, 12%, 30% and 42%, respectively.

Some of the dielectric layers disclosed herein may be thermally stable and chemically resistive, increasing their manufacturability and performance characteristics over conventional materials. For example, the dielectric material 130 may be chosen to have particular thermal and/or chemical properties (e.g., resistance to hydrofluoric acid), which may then be “inherited” when the dielectric layer 100 is formed from the dielectric material 130. Various ones of the dielectric layers described herein may thus enable the continued scaling of metallization pitch and capacitance while retaining acceptable mechanical performance.

Additionally, as discussed above, some embodiments of processes for fabricating the dielectric layers disclosed herein may include patterning via a DSA material. Conventional DSA techniques are known to suffer from imperfections in self-assembly (e.g., missing aggregations in an otherwise regular arrangement). These imperfections have impeded the adoption of DSA techniques in many manufacturing processes. However, the use of DSA techniques in the fabrication of the dielectric layers disclosed herein is relatively insensitive to errors in the pattern (resulting in, e.g., the absence or irregular positioning of a small number of elongate pores), as long as the bulk characteristics of the resulting dielectric layer are as desired. Thus, the fabrication processes involving DSA materials disclosed herein may take advantage of the strengths of DSA techniques while being advantageously less sensitive to the errors typical to DSA techniques.

In some embodiments, the hardmasks may be omitted from the method 1600, and the dielectric material may be patterned directly from the DSA material. Such embodiments may be suitable for thin dielectric materials, or for thicker dielectric materials when the dielectric material is a crosslinked hydrocarbon polymer (e.g., such that a plasma etch process used to etch the dielectric material has a low ion bombardment component and thus the etch may act more like an ash), for example. For a crosslinked hydrocarbon polymer dielectric material, the DSA material may be deposited directly on the dielectric material, and the template pores of the DSA material may be controllably transferred to the dielectric material (along with controlling the radial expansion of the elongate pores of the dielectric material), under suitable conditions.

The dielectric layers disclosed herein may be incorporated into any suitable application in IC or other devices. For example, the dielectric layers disclosed herein may be used as a thin film in metal oxide semiconductor (MOS) or complementary metal oxide semiconductor (CMOS) devices. Moreover, the dielectric layers may be oriented in a device such that the axis along which the dielectric layers have the greatest mechanical stiffness is aligned with the direction in which the greatest mechanical stresses are expected to be exerted. For example, in some manufacturing processes, the largest mechanical stresses encountered by an ILD may be in the vertical direction (along the axis 106) (e.g., from stresses induced during die/package assembly from mismatches in the coefficient of thermal expansion (CTE) of the silicon die and the package); in such manufacturing processes, the ILD may be formed as one of the dielectric layers disclosed herein, with the elongate pores arranged so that their longitudinal axes are oriented in the vertical direction (along the axis 106).

FIG. 17 is a cross-sectional view of a portion of an IC device 1700 including a dielectric layer 1724 which may serve as an ILD, in accordance with some embodiments. The dielectric layer 1724 of the IC device 1700 may be arranged in an ILD stack having conductive interconnect structures 1716 to route electrical signals within the IC device 1700, as discussed below. The dielectric layer 1724 may be disposed between the conductive interconnect structures 1716 and a substrate 1704, and may include any of the dielectric layers described herein (e.g., those described with reference to the dielectric layer 100).

The IC device 1700 may be formed on a substrate 1704 (e.g., the substrate 110 of FIG. 1, which may include a silicon wafer). The substrate 1704 may be a semiconductor substrate composed of semiconductor material systems including, for example, N-type or P-type materials systems. The substrate 1704 may include, for example, a crystalline substrate formed using a bulk silicon or a silicon-on-insulator substructure, and may serve as the substrate 110 of FIG. 1. Although a few examples of materials from which the substrate 1704 may be formed are described here, any material that may serve as a foundation upon which the IC device 1700 may be used in accordance with various embodiments.

In some embodiments, the IC device 1700 includes a device layer 1718 disposed on the substrate 1704. The device layer 1718 may include features of one or more transistors 1708 formed on the substrate 1704. The device layer 1718 may include, for example, one or more source and/or drain (S/D) 1710, a gate 1712 to control current flow in the transistor(s) 1708 between the S/D regions 1710, and one or more S/D contacts 1714 to route electrical signals to/from the S/D regions 1710. The transistor(s) 1708 may include additional features not depicted for the sake of clarity such as device isolation regions, gate contacts, and the like. The transistor(s) 1708 are not limited to the type and configuration depicted in FIG. 17 and may include a wide variety of other types and configurations such as, for example, planar and non-planar transistors such as dual- or double-gate transistors, tri-gate transistors, and all-around gate (AAG) or wrap-around gate transistors, some of which may be referred to as FinFETs (Field Effect Transistors). In some embodiments, the device layer 1718 includes one or more transistors or memory cells of a logic device or a memory device, or combinations thereof.

Electrical signals such as, for example, power and/or input/output (I/O) signals may be routed to and/or from the transistor(s) 1708 of the device layer 1706 through one or more interconnect layers 1720 and 1722 disposed on the device layer 1706. For example, electrically conductive features of the device layer 1718 such as, for example, the gate 1712 and S/D contacts 1714 may be electrically coupled with the interconnect structures 1716 of the interconnect layers 1720 and 1722. The one or more interconnect layers 1720 and 1722 may form an ILD stack of the IC device 1700. The interconnect structures 1716 may be configured within the interconnect layers 1720 and 1722 to route electrical signals according to a wide variety of designs and is not limited to the particular configuration of interconnect structures 1716 depicted in FIG. 17.

For example, in some embodiments, the interconnect structures 1716 may include trench structures (sometimes referred to as “lines”) and/or via structures (sometimes referred to as “holes”) filled with an electrically conductive material such as a metal. In some embodiments, the interconnect structures 1716 may comprise copper or another suitable electrically conductive material.

The interconnect layers 1720 and 1722 may include the dielectric layer 1724 disposed between the interconnect structures 1716, as can be seen. Any of the layers or structures below a portion of the dielectric layer 1724 may serve as the substrate 110 of FIG. 1. The dielectric layer 1724 may include any one or more of the dielectric layers discussed herein (e.g., any of the embodiments of the dielectric layer 100). In some embodiments, the dielectric layer 1724 may include multiple different dielectric layers, some of which may comport with the dielectric layers discussed herein (e.g., the dielectric layer 100) and others of which may be conventional dielectric materials.

In some embodiments, a first interconnect layer 1718 (referred to as Metal 1 or “M1”) may be formed directly on the device layer 1718. In some embodiments, the first interconnect layer 1720 may include some of the interconnect structures 1716, which may be coupled with contacts (e.g., the S/D contacts 1714) of the device layer 1718.

Additional interconnect layers (not shown for ease of illustration) may be formed directly on the first interconnect layer 1720, and may include interconnect structures 1716 to couple with interconnect structures of the first interconnect layer 1720.

The IC device 1700 may one or more bond pads 1726 formed on the interconnect layers 1718, 1720 and 1722. The bond pads 1726 may be electrically coupled with the interconnect structures 1716 and configured to route the electrical signals of transistor(s) 1708 to other external devices. For example, solder bonds may be formed on the one or more bond pads 1726 to mechanically and/or electrically couple a chip including the IC device 1700 with another component such as a circuit board. The IC device 1700 may have other alternative configurations to route the electrical signals from the interconnect layers 1718, 1720 and 1722 than depicted in other embodiments. In other embodiments, the bond pads 1726 may be replaced by or may further include other analogous features (e.g., posts) that route the electrical signals to other external components.

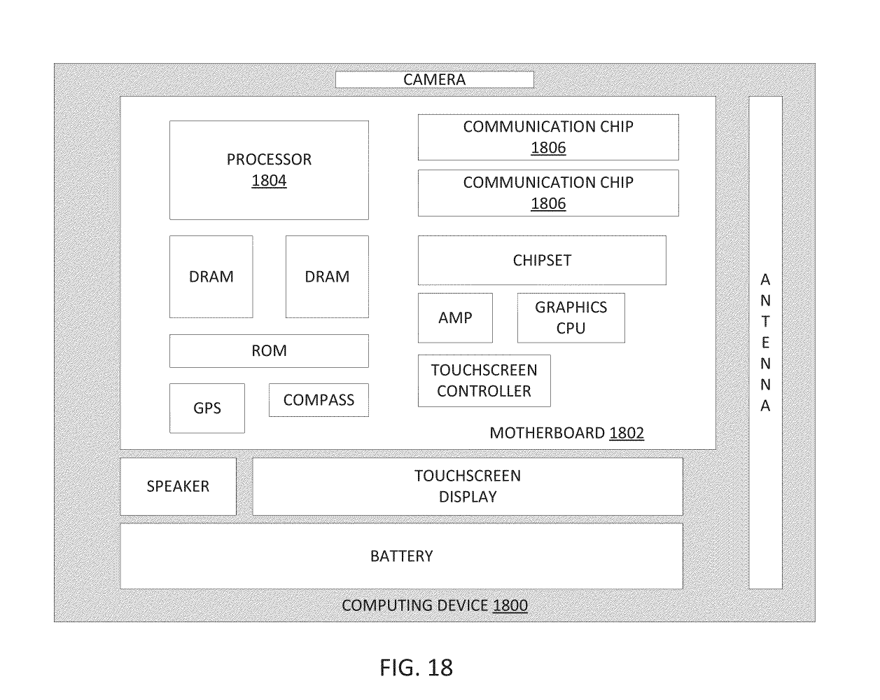

Embodiments of the present disclosure may be implemented into a system using any suitable hardware and/or software to configure as desired. FIG. 18 schematically illustrates a computing device 1800 in accordance with one implementation. In some embodiments, a dielectric layer as disclosed herein may be used as a dielectric (e.g., an ILD) in one or more components of computing device 1800.

The computing device 1800 may house a board such as motherboard 1802. The motherboard 1802 may include a number of components, including but not limited to a processor 1804 and at least one communication chip 1806. The processor 1804 may be physically and electrically coupled to the motherboard 1802. In some implementations, the at least one communication chip 1806 may also be physically and electrically coupled to the motherboard 1802. In further implementations, the communication chip 1806 may be part of the processor 1804. The term “processor” may refer to any device or portion of a device that processes electronic data from registers and/or memory to transform that electronic data into other electronic data that may be stored in registers and/or memory.

Depending on its applications, computing device 1800 may include other components that may or may not be physically and electrically coupled to the motherboard 1802. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 1806 may enable wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. The communication chip 1806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1806 may operate in accordance with other wireless protocols in other embodiments.

The computing device 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The communication chip 1806 may also include an IC package assembly that may include a dielectric layer as described herein. In further implementations, another component (e.g., memory device or other integrated circuit device) housed within the computing device 1800 may contain an IC package assembly that may include a dielectric layer as described herein.

In various implementations, the computing device 1800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1800 may be any other electronic device that processes data. In some embodiments, the techniques described herein are implemented in a high-performance computing device. In some embodiments, the techniques described herein are implemented in handheld computing devices.

The following paragraphs describe illustrative embodiments of the present disclosures. Example 1 is a dielectric layer, including: a dielectric material having a first surface, a second surface opposite to the first surface and spaced away from the first surface in a direction defined by an axis, and an interior between the first and second surfaces, wherein the first surface is disposed between the second surface and a substrate, and wherein the dielectric material has a Young's modulus of E₀ in the direction defined by the axis; and a plurality of elongate pores in the dielectric material, wherein individual elongate pores of the plurality of elongate pores extend from the second surface into the interior of the dielectric material and have a longitudinal axis substantially parallel to the axis. The plurality of elongate pores may provide the dielectric layer with a porosity, p, greater than approximately 30%, and the dielectric layer may have a Young's modulus approximately equal to E₀*(1−p) in the direction defined by the axis.

Example 2 may include the subject matter of Example 1, and may further specify that each of the individual elongate pores is approximately cylindrical.

Example 3 may include the subject matter of any of Examples 1-2, and may further specify that each of the individual elongate pores has a bottom surface and the bottom surface is spaced away from the first surface of the dielectric material.

Example 4 may include the subject matter of any of Examples 1-3, and may further specify that the dielectric layer has a dielectric constant of less than approximately 2.0.

Example 5 may include the subject matter of any of Examples 1-4, and may further specify that the plurality of elongate pores are regularly arranged on the second surface of the dielectric material over a short, medium, or long range.

Example 6 may include the subject matter of any of Examples 1-5, and may further include a cap disposed on the second surface to cover openings of one or more of the plurality of elongate pores on the second surface.

Example 7 may include the subject matter of any of Examples 1-6, and may further specify that the dielectric layer has a porosity greater than approximately 60%.

Example 8 may include the subject matter of any of Examples 1-7, and may further specify that the dielectric layer has a porosity between approximately 60% and 80% and has a Young's modulus greater than or equal to 5 gigapascals in the direction defined by the axis.

Example 9 is a dielectric layer, including: a dielectric material having a first surface, a second surface opposite to the first surface and spaced away from the first surface in a direction defined by an axis, and an interior between the first and second surfaces, wherein the first surface is disposed between the second surface and a substrate; and a plurality of elongate pores in the dielectric material, wherein individual elongate pores of the plurality of elongate pores extend from the second surface into the interior of the dielectric material and have a longitudinal axis substantially parallel to the axis. The dielectric layer may have a porosity greater than approximately 50%.

Example 10 may include the subject matter of Example 9, and may further specify that the dielectric layer has a porosity greater than approximately 60%.

Example 11 may include the subject matter of any of Examples 9-10, and may further specify that the dielectric layer has a porosity between approximately 60% and 80% and has a Young's modulus greater than or equal to 5 gigapascals in the direction defined by the axis.

Example 12 may include the subject matter of any of Examples 9-11, and may further specify that each of the individual elongate pores is approximately cylindrical.

Example 13 may include the subject matter of any of Examples 9-12, and may further specify that the dielectric layer has a dielectric constant of less than approximately 2.0.

Example 14 may include the subject matter of any of Examples 9-13, and may further specify that the plurality of elongate pores are regularly arranged on the second surface of the dielectric material over a short, medium, or long range.

Example 15 may include the subject matter of any of Examples 9-14, and may further include a cap disposed on the second surface to cover openings of one or more of the plurality of elongate pores on the second surface.

Example 16 is a method of fabricating a dielectric layer, including: depositing a hardmask on a second surface of a dielectric material, the second surface opposite to a first surface of the dielectric material that is disposed between the second surface and a substrate; depositing a directed self-assembly material on the deposited hardmask; selectively etching the directed self-assembly material to form a first plurality of template pores in the directed self-assembly material; etching the hardmask to form a second plurality of template pores in the hardmask, wherein an individual pore of the second plurality of template pores has an area greater than an area of a corresponding individual pore of the first plurality of template pores; and etching the dielectric material to form a plurality of pores, wherein individual pores of the plurality of pores extend from the second surface towards the first surface.

Example 17 may include the subject matter of Example 16, and may further specify that the second surface is spaced away from the first surface in a direction defined by an axis, and that each of the individual pores has a longitudinal axis substantially parallel to the axis.

Example 18 may include the subject matter of any of Examples 16-17, and may further specify that: the hardmask includes first and second hardmasks; the first hardmask is disposed between the second hardmask and the second surface of the dielectric material; and etching the hardmask to form a second plurality of template pores in the hardmask includes etching the second hardmask to form a third plurality of template pores in the second hardmask, wherein an individual pore of the third plurality of template pores has an area approximately equal to the area of a corresponding individual pore of the first plurality of template pores.

Example 19 may include the subject matter of any of Examples 16-18, and may further specify that each of the individual pores of the first plurality of template pores has a diameter of approximately 14 nanometers.

Example 20 may include the subject matter of any of Examples 16-19, and may further specify that the directed self-assembly material includes polystyrene-block-poly methyl methacrylate (PS-PMMA).

Example 21 may include the subject matter of any of Examples 16-20, and may further include: after etching the dielectric material to form the plurality of pores, filling the plurality of pores with a fill material including a polymer or refractory material; and after filling the plurality of pores, patterning the dielectric material.

Example 22 may include the subject matter of Example 21, and may further include, after patterning the dielectric material, removing the fill material.

Example 23 may include the subject matter of any of Examples 16-22, and may further include, after etching the dielectric material to form the plurality of pores, providing a cap on openings of the plurality of pores on the second surface.

Example 24 is an integrated circuit, including: a substrate; conductive interconnects; and an interlayer dielectric disposed between the conductive interconnects and the substrate. The interlayer dielectric may include: a dielectric material having a first surface, a second surface opposite to the first surface and spaced away from the first surface in a direction defined by an axis, and an interior between the first and second surfaces, wherein the first surface is disposed between the second surface and a substrate and wherein the dielectric material has a Young's modulus of E₀ in the direction defined by the axis, and a plurality of elongate pores in the dielectric material, wherein individual elongate pores of the plurality of elongate pores extend from the second surface into the interior of the dielectric material and have a longitudinal axis substantially parallel to the axis, wherein the plurality of elongate pores provide the interlayer dielectric with a porosity, p, greater than approximately 30%, and the interlayer dielectric has a Young's modulus approximately equal to E₀*(1−p) in the direction defined by the axis.

Example 25 may include the subject matter of Example 24, and may further specify that the interlayer dielectric includes a trench, and a portion of the conductive interconnects is disposed in the trench.

Example 26 may include the subject matter of any of Examples 24-25, and may further specify that the interlayer dielectric has a dielectric constant of less than approximately 2.0.

Example 27 may include the subject matter of any of Examples 24-26, and may further specify that the interlayer dielectric has a porosity greater than approximately 40%.

Example 28 may include the subject matter of any of Examples 24-27, and may further specify that the substrate includes one or more additional metal layers.

Example 29 may include the subject matter of any of Examples 24-28, and may further specify that the plurality of elongate pores are regularly arranged on the second surface of the dielectric material over a short, medium, or long range.

Example 30 is an integrated circuit, including a substrate, conductive interconnects, and an interlayer dielectric including any of the dielectric layers disclosed herein.

The description herein of illustrated implementations, including what is described in the Abstract, is not intended to be exhaustive or to limit the present disclosure to the precise forms disclosed. While specific implementations and examples are described herein for illustrative purposes, various equivalent modifications are possible within the scope of the disclosure, as those skilled in the relevant art will recognize. These modifications may be made to the disclosure in light of the above detailed description.

What is claimed is:

1. A dielectric layer, comprising:
a dielectric material having a first surface, a second surface opposite to the first surface and spaced away from the first surface in a direction defined by an axis, and an interior between the first and second surfaces, wherein the first surface is disposed between the second surface and a substrate, and wherein the dielectric material has a Young's modulus of E₀ in the direction defined by the axis; and
a plurality of elongate pores in the dielectric material, wherein individual elongate pores of the plurality of elongate pores extend from the second surface into the interior of the dielectric material and have a longitudinal axis substantially parallel to the axis;
wherein the plurality of elongate pores provide the dielectric layer with a porosity, p, greater than approximately 30%, and the dielectric layer has a Young's modulus approximately equal to E₀*(1−p) in the direction defined by the axis.

2. The dielectric layer of claim 1, wherein each of the individual elongate pores is approximately cylindrical.

3. The dielectric layer of claim 1, wherein each of the individual elongate pores has a bottom surface and the bottom surface is spaced away from the first surface of the dielectric material.

4. The dielectric layer of claim 1, having a dielectric constant of less than approximately 2.0.

5. The dielectric layer of claim 1, wherein the plurality of elongate pores are regularly arranged on the second surface of the dielectric material over a short, medium, or long range.

6. The dielectric layer of claim 1, further comprising a cap disposed on the second surface to cover openings of one or more of the plurality of elongate pores on the second surface.

7. A dielectric layer, comprising:
a dielectric material having a first surface, a second surface opposite to the first surface and spaced away from the first surface in a direction defined by an axis, and an interior between the first and second surfaces, wherein the first surface is disposed between the second surface and a substrate; and
a plurality of elongate pores in the dielectric material, wherein individual elongate pores of the plurality of elongate pores extend from the second surface into the interior of the dielectric material and have a longitudinal axis substantially parallel to the axis;
wherein the dielectric layer has a porosity greater than approximately 50%.

8. The dielectric layer of claim 7, having a porosity greater than approximately 40%.

9. The dielectric layer of claim 7, having a porosity between approximately 60% and 80% and having a Young's modulus greater than or equal to 5 gigapascals in the direction defined by the axis.

10. The dielectric layer of claim 7, wherein each of the individual elongate pores is approximately cylindrical.

11. The dielectric layer of claim 7, having a dielectric constant of less than approximately 2.0.

12. A method of fabricating a dielectric layer, comprising:
depositing a hardmask on a second surface of a dielectric material, the second surface opposite to a first surface of the dielectric material that is disposed between the second surface and a substrate;
depositing a directed self-assembly material on the deposited hardmask;
selectively etching the directed self-assembly material to form a first plurality of template pores in the directed self-assembly material;
etching the hardmask to form a second plurality of template pores in the hardmask, wherein an individual pore of the second plurality of template pores has an area greater than an area of a corresponding individual pore of the first plurality of template pores; and
etching the dielectric material to form a plurality of pores, wherein individual pores of the plurality of pores extend from the second surface towards the first surface.

13. The method of claim 12, wherein the second surface is spaced away from the first surface in a direction defined by an axis, and each of the individual pores has a longitudinal axis substantially parallel to the axis.

14. The method of claim 12, wherein:
the hardmask comprises first and second hardmasks;
the first hardmask is disposed between the second hardmask and the second surface of the dielectric material; and
etching the hardmask to form a second plurality of template pores in the hardmask comprises etching the second hardmask to form a third plurality of template pores in the second hardmask, wherein an individual pore of the third plurality of template pores has an area approximately equal to the area of a corresponding individual pore of the first plurality of template pores.

15. The method of claim 12, wherein each of the individual pores of the first plurality of template pores has a diameter of approximately 14 nanometers.

16. The method of claim 12, wherein the directed self-assembly material comprises polystyrene-block-poly methyl methacrylate (PS-PMMA).

17. The method of claim 12, further comprising:
after etching the dielectric material to form the plurality of pores, filling the plurality of pores with a fill material comprising a polymer or refractory material; and
after filling the plurality of pores, patterning the dielectric material.

18. The method of claim 17, further comprising:
after patterning the dielectric material, removing the fill material.

19. The method of claim 12, further comprising:
after etching the dielectric material to form the plurality of pores, providing a cap on openings of the plurality of pores on the second surface.

20. An integrated circuit, comprising:
a substrate;
conductive interconnects; and
an interlayer dielectric disposed between the conductive interconnects and the substrate, the interlayer dielectric comprising:
a dielectric material having a first surface, a second surface opposite to the first surface and spaced away from the first surface in a direction defined by an axis, and an interior between the first and second surfaces, wherein the first surface is disposed between the second surface and a substrate and wherein the dielectric material has a Young's modulus of E₀ in the direction defined by the axis, and
a plurality of elongate pores in the dielectric material, wherein individual elongate pores of the plurality of elongate pores extend from the second surface into the interior of the dielectric material and have a longitudinal axis substantially parallel to the axis,
wherein the plurality of elongate pores provide the interlayer dielectric with a porosity, p, greater than approximately 30%, and the interlayer dielectric has a Young's modulus approximately equal to E₀*(1−p) in the direction defined by the axis.

21. The integrated circuit of claim 20, wherein the interlayer dielectric comprises a trench, and a portion of the conductive interconnects is disposed in the trench.

22. The integrated circuit of claim 20, wherein the interlayer dielectric has a dielectric constant of less than approximately 2.0.

23. The integrated circuit of claim 20, wherein the interlayer dielectric has a porosity greater than approximately 40%.

24. The integrated circuit of claim 20, wherein the substrate comprises one or more additional metal layers.

25. The integrated circuit of claim 20, wherein the plurality of elongate pores are regularly arranged on the second surface of the dielectric material over a short, medium, or long range.
